(19) United States
(12) Patent Application Publication
(10) Pub. No.: US 2019/0158021 A1
(43) Pub. Date: May 23, 2019

(54) TEMPERATURE-COMPENSATED CRYSTAL OSCILLATOR, AND ELECTRONIC DEVICE USING THE SAME

(71) Applicant: SEIKO EPSON CORPORATION, Tokyo (JP)

(72) Inventor: Shigeyuki SAKUMA, Sakata-shi (JP)

(73) Assignee: SEIKO EPSON CORPORATION, Tokyo (JP)

(21) Appl. No.: 16/198,035

(22) Filed: Nov. 21, 2018

(30) Foreign Application Priority Data
Nov. 22, 2017 (JP) 2017-224381

(51) Int. Cl. H03B 5/04; H01L 29/94; H03B 5/36

(52) U.S. Cl. CPC H03B 5/04; H01L 29/94; H03B 2200/004; H03B 2201/0208; H03B 5/368

(57) ABSTRACT

This temperature-compensated crystal oscillator includes: a crystal resonator; first and second MOS-type variable capacitance elements, each having one end electrically connected to first or second electrodes of the crystal resonator; and a temperature compensation circuit that applies a temperature compensation voltage, which changes in accordance with a temperature, to other ends of the first and second MOS-type variable capacitance elements. The first MOS-type variable capacitance element includes a first back gate provided within a semiconductor substrate, and an N-type first gate electrode provided above the first back gate with an insulating film interposed therebetween; and the second MOS-type variable capacitance element includes a second back gate provided within the semiconductor substrate and having the same conductivity type as the first back gate, and a P-type second gate electrode provided above the second back gate with an insulating film interposed therebetween.

### BACKGROUND

### 1. Technical Field

The present invention relates to a temperature-compensated crystal oscillator in which the oscillation frequency is temperature-compensated using a variable capacitance element. The invention also relates to an electronic device and the like that use such a temperature-compensated crystal oscillator.

### 2. Related Art

A temperature-compensated crystal oscillator (TCXO) adjusts the oscillation frequency to compensate for temperature changes by using, for example, a MOS-type variable capacitance element (MOS capacitor) as a variable capacitance element, in which the capacitance value changes in accordance with a voltage applied to the element. In a MOS-type variable capacitance element, making the gate insulator thinner is conceivable as a way to broaden the variation range of the capacitance value. However, making the gate insulator thinner causes an increase in gate leakage, and there is thus a limit to how thin the gate insulator can be made. Accordingly, a plurality of MOS-type variable capacitance elements are used, with the elements being operated in mutually-different bias regions.

For example, a first MOS-type variable capacitance element and a second MOS-type variable capacitance element are connected in parallel, in terms of AC current, through a crystal resonator. A first bias voltage is applied to one end of the first MOS-type variable capacitance element, and a second bias voltage, which is different from the first bias voltage, is applied to one end of the second MOS-type variable capacitance element. A temperature compensation voltage is applied to the other ends of the first and second MOS-type variable capacitance elements, which causes the first and second MOS-type variable capacitance elements to operate in mutually-different bias regions. This makes it possible to broaden the range in which the oscillation frequency of the temperature-compensated crystal oscillator can vary.

However, in this case, a bias circuit that shifts the bias voltage is required in order to generate the two mutually-different bias voltages. Adding such a bias circuit increases the circuit scale and makes the temperature-compensated crystal oscillator more expensive. The bias circuit also produces noise, which makes it difficult to improve the oscillation characteristics of the temperature-compensated crystal oscillator.

As related technology, JP-A-11-88052 discloses a temperature-compensated crystal oscillator that has a broad frequency adjustment range within the range of used voltages, that can simplify the circuitry for generating temperature compensation control signals, and that has a broad temperature compensation range even in the narrow voltage range of the control signals. This temperature-compensated crystal oscillator includes: a crystal oscillation circuit having an AT-cut crystal resonator, and a MOS-type capacitor serving as a variable capacitance for oscillation frequency adjustment; a first control signal generation circuit for temperature compensation, which is connected to one terminal of the MOS-type capacitor; and a second control signal generation circuit for temperature compensation, which is connected to another terminal of the MOS-type capacitor.

Although the temperature-compensated crystal oscillator according to JP-A-11-88052 uses only one MOS-type capacitor, the oscillator also requires the first control signal generation circuit and the second control signal generation circuit for temperature compensation. This increases the circuit scale and makes the temperature-compensated crystal oscillator more expensive. The control signal generation circuits also produce noise, which makes it difficult to improve the oscillation characteristics of the temperature-compensated crystal oscillator.

### SUMMARY

Thus in light of the foregoing, an advantage of some aspects of the invention is to provide a temperature-compensated crystal oscillator capable of broadening the oscillation frequency variation range without increasing the scale of the circuitry for generating a voltage to be applied to a MOS-type variable capacitance element. Another advantage of some aspects of the invention is to provide an electronic device and the like employing such a temperature-compensated crystal oscillator.

To at least partially achieve the above-described advantage, a temperature-compensated crystal oscillator according to a first aspect of the invention includes: a crystal resonator including a first electrode and a second electrode; a first MOS-type variable capacitance element having one end electrically connected to the first or second electrode of the crystal resonator; a second MOS-type variable capacitance element having one end electrically connected to the first or second electrode of the crystal resonator; and a temperature compensation circuit that applies a temperature compensation voltage, which changes in accordance with a temperature, to other ends of the first and second MOS-type variable capacitance elements. The first MOS-type variable capacitance element includes a first back gate provided within a semiconductor substrate, and an N-type first gate electrode provided above the first back gate with an insulating film interposed between the first back gate and the first gate electrode. The second MOS-type variable capacitance element includes a second back gate provided within the semiconductor substrate and having the same conductivity type as the first back gate, and a P-type second gate electrode provided above the second back gate with an insulating film interposed between the second back gate and the second gate electrode.

According to the first aspect of the invention, the first MOS-type variable capacitance element including the N-type first gate electrode and the second MOS-type variable capacitance element including the P-type second gate electrode have mutually-different flat band voltages. Accordingly, connecting the first and second MOS-type variable capacitance elements in parallel in terms of AC current makes it possible to broaden the range of variation of the oscillation frequency without increasing the scale of the circuitry for generating the voltage applied to the MOS-type variable capacitance elements.

Additionally, a temperature-compensated crystal oscillator according to a second aspect of the invention includes: a crystal resonator including a first electrode and a second electrode; a first MOS-type variable capacitance element having one end electrically connected to the first or second electrode of the crystal resonator; a second MOS-type variable capacitance element having one end electrically connected to the first or second electrode of the crystal resonator; and a temperature compensation circuit that applies a temperature compensation voltage, which changes in accordance with a temperature, to other ends of the first and second MOS-type variable capacitance elements, wherein the first MOS-type variable capacitance element includes a first back gate provided within a semiconductor substrate, and a first gate electrode provided above the first back gate with an insulating film interposed between the first back gate and the first gate electrode, the first gate electrode including an N-type part and a P-type part; and the second MOS-type variable capacitance element includes a second back gate provided within the semiconductor substrate and having the same conductivity type as the first back gate, and a second gate electrode provided above the second back gate with an insulating film interposed between the second back gate and the second gate electrode, the second gate electrode including an N-type part and a P-type part.

According to the second aspect of the invention, the first and second MOS-type variable capacitance elements have mutually-different flat band voltages between the N-type parts and the P-type parts of the first and second gate electrodes. Accordingly, connecting the first and second MOS-type variable capacitance elements in parallel in terms of AC current makes it possible to broaden the range of variation of the oscillation frequency without increasing the scale of the circuitry for generating the voltage applied to the MOS-type variable capacitance elements.

The temperature-compensated crystal oscillator according to the first or second aspects of the invention may further include an amplifier circuit that is connected between the first electrode and the second electrode of the crystal resonator and that carries out inverse amplifying operations. The crystal resonator is therefore inserted into a feedback loop of the amplifier circuit, and the amplifier circuit can oscillate using the resonance characteristics of the crystal resonator.

Additionally, the first gate electrode of the first MOS-type variable capacitance element and the second gate electrode of the second MOS-type variable capacitance element may be electrically connected to the first and second electrodes, respectively, of the crystal resonator; and the temperature compensation circuit may supply the temperature compensation voltage to the first back gate of the first MOS-type variable capacitance element and the second back gate of the second MOS-type variable capacitance element. In this case, the same temperature compensation voltage is supplied to the first and second back gates, and thus the first and second back gates can be integrated.

Furthermore, an electronic device according to a third aspect of the invention includes any of the above-described temperature-compensated crystal oscillators. According to the third aspect of the invention, an electronic device capable of operating accurately throughout a broad temperature range can be provided at low cost by using the temperature-compensated crystal oscillator, which broadens the range of variation of the oscillation frequency without increasing the scale of the circuitry for generating the voltage applied to the MOS-type variable capacitance elements.

### BRIEF DESCRIPTION OF THE DRAWINGS

The invention will be described with reference to the accompanying drawings, wherein like numbers reference like elements.

FIG. 1 is a circuit diagram illustrating an example of the configuration of a temperature-compensated crystal oscillator according to a first embodiment of the invention.

FIG. 2 is a cross-sectional view illustrating an example of the configuration of a first MOS-type variable capacitance element illustrated in FIG. 1.

FIG. 3 is a cross-sectional view illustrating an example of the configuration of a second MOS-type variable capacitance element illustrated in FIG. 1.

FIG. 4 is a diagram illustrating an example of capacitance changes in a known temperature-compensated crystal oscillator.

FIG. 5 is a diagram illustrating an example of capacitance changes in the temperature-compensated crystal oscillator according to the first embodiment.

FIG. 6 is a cross-sectional view illustrating an example of the configuration of a MOS-type variable capacitance element according to a second embodiment.

FIG. 7 is a diagram illustrating an example of capacitance changes in the temperature-compensated crystal oscillator according to the second embodiment.

FIG. 8 is a block diagram illustrating an example of the configuration of an electronic device according to an embodiment of the invention.

### DESCRIPTION OF EXEMPLARY EMBODIMENTS

Hereinafter, embodiments of the invention will be described in detail with reference to the drawings. Note that identical constituent elements are given identical reference signs, and descriptions thereof will not be repeated.

### First Embodiment

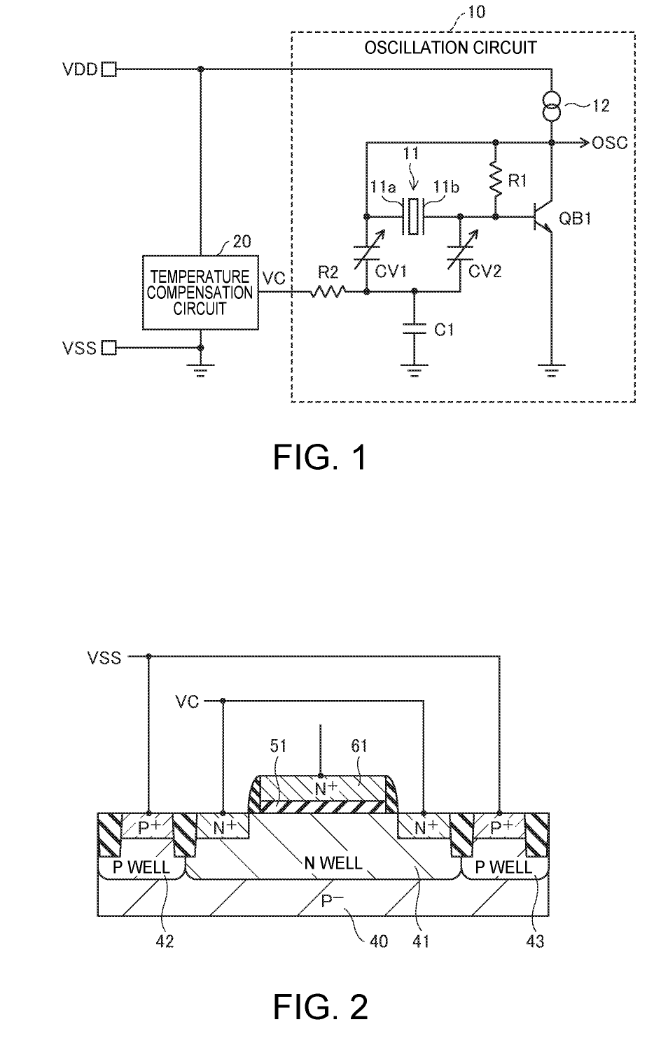

FIG. 1 is a circuit diagram illustrating an example of the configuration of a temperature-compensated crystal oscillator according to a first embodiment of the invention. This temperature-compensated crystal oscillator (TCXO) oscillates in response to the supply of a high potential-side source potential VDD and a low potential-side source potential VSS which is lower than the source potential VDD (a ground potential of 0 V, in the example illustrated in FIG. 1), and generates an oscillation signal OSC through the oscillation.

As illustrated in FIG. 1, the temperature-compensated crystal oscillator includes an oscillation circuit 10 and a temperature compensation circuit 20. The oscillation circuit 10 includes a crystal resonator 11, a constant current source 12, an NPN bipolar transistor QB1, resistors R1 and R2, a first MOS-type variable capacitance element CV1, a second MOS-type variable capacitance element CV2, and a capacitor C1. Here, at least some of the constituent elements of the temperature-compensated crystal oscillator, aside from the crystal resonator 11, may be built into a semiconductor device (IC).

The crystal resonator 11 includes a first electrode 11a and a second electrode 11b. The transistor QB1 and the resistor R1 are connected between the first electrode 11a and the second electrode 11b of the crystal resonator 11 to constitute an amplifier circuit carrying out inverse amplification. The crystal resonator 11 is therefore inserted into a feedback loop of the amplifier circuit, and the amplifier circuit can oscillate using the resonance characteristics of the crystal resonator 11. Another circuit such as an inverter can also be used as the amplifier circuit.

The transistor QB1 includes a collector connected to the first electrode 11a of the crystal resonator 11, an emitter connected to the source potential VSS line, and a base connected to the second electrode 11b of the crystal resonator 11. The constant current source 12 includes a current mirror circuit, for example, and one of transistors constituting the current mirror circuit supplies a constant current to the collector of the transistor QB1. The resistor R1 is connected between the collector and the base of the transistor QB1, and supplies a base current to the transistor QB1.

The first MOS-type variable capacitance element CV1 has one end electrically connected to the first electrode 11a or the second electrode 11b of the crystal resonator 11. Likewise, the second MOS-type variable capacitance element CV2 has one end electrically connected to the first electrode 11a or the second electrode 11b of the crystal resonator 11. In the example of FIG. 1, one end of the first MOS-type variable capacitance element CV1 is electrically connected to the first electrode 11a of the crystal resonator 11, and one end of the second MOS-type variable capacitance element CV2 is electrically connected to the second electrode 11b of the crystal resonator 11.

Alternatively, one set including a first MOS-type variable capacitance element CV1 and a second MOS-type variable capacitance element CV2 may be provided, with the one ends of those elements electrically connected to the first electrode 11a of the crystal resonator 11, and another set including a first MOS-type variable capacitance element CV1 and a second MOS-type variable capacitance element CV2 may be provided, with the one ends of those elements electrically connected to the second electrode 11b of the crystal resonator 11. The capacitor C1 is connected between the other ends of the first MOS-type variable capacitance element CV1 and the second MOS-type variable capacitance element CV2, and the source potential VSS line.

During inverse amplification by the transistor QB1, the oscillation signal OSC, which is generated by the collector, is fed back to the base through the crystal resonator 11 and the resistor R1, which are connected in parallel. At this time, the crystal resonator 11 vibrates under an AC voltage applied by the transistor QB1. This vibration is greatly excited at a unique resonance frequency, and the crystal resonator 11 acts as a negative resistance.

As a result, the oscillation circuit 10 oscillates at an oscillation frequency determined mainly by the resonance frequency of the crystal resonator 11. However, fine adjustments can be made to the oscillation frequency of the oscillation circuit 10 by changing the capacitance values of the first MOS-type variable capacitance element CV1 and the second MOS-type variable capacitance element CV2. The capacitance values of the first MOS-type variable capacitance element CV1 and the second MOS-type variable capacitance element CV2 change in accordance with the voltages applied across both ends thereof.

The temperature compensation circuit 20 includes a temperature sensor, and applies a temperature compensation voltage VC, which varies with temperature, to the other ends of the first MOS-type variable capacitance element CV1 and the second MOS-type variable capacitance element CV2, via the resistor R2. The temperature sensor includes, for example, a PN junction diode, a transistor, or a thermistor, and an amplifier circuit. The amplifier circuit detects the surrounding temperature and outputs a detection signal. The temperature compensation circuit 20 generates the temperature compensation voltage VC which cancels out temperature characteristics of the resonance frequency of the crystal resonator 11 by, for example, adding a voltage expressed as a linear function of the temperature detected by the temperature sensor and a voltage expressed as a cubic function of the temperature.

FIG. 2 is a cross-sectional view illustrating an example of the configuration of the first MOS-type variable capacitance element illustrated in FIG. 1. As illustrated in FIG. 2, for example, an N well 41 and P wells 42 and 43 are provided within a P-type semiconductor substrate 40 formed from silicon (Si) containing P-type impurities. Furthermore, an N-type contact region (N⁺) for supplying the temperature compensation voltage VC to the N well 41 is provided within the N well 41, and P-type contact regions (P⁺) for supplying the source potential VSS to the semiconductor substrate 40 through the P wells 42 and 43 are provided within the P wells 42 and 43.

The first MOS-type variable capacitance element CV1 includes a first back gate constituted by the N well 41 provided in the semiconductor substrate 40, and an N-type first gate electrode 61 arranged above the first back gate with an insulating film (gate insulator) 51 interposed therebetween. The first gate electrode 61 is formed of polysilicon containing N-type impurities, for example. Here, the effective fixed charge density at the boundary between the insulating film 51 and the first gate electrode 61 is found by multiplying the flat-band voltage shift of the first gate electrode 61 by the capacitance of the insulating film 51.

Generally, a state where the surface potential of a semiconductor substrate is zero and the semiconductor device band has flattened is called a “flat band”. Even in ideal cases (where no charge is present at the boundary of the insulation film, within the insulation film, and so on), setting the gate voltage to 0 V will not produce a flat band, due to a difference between the Fermi level of the semiconductor substrate and the work function of the gate electrode. A flat band is produced by applying a voltage equivalent to that difference to the gate electrode, and that gate voltage corresponds to an ideal flat band voltage. The voltage difference from the ideal case is called the “flat band voltage shift”.

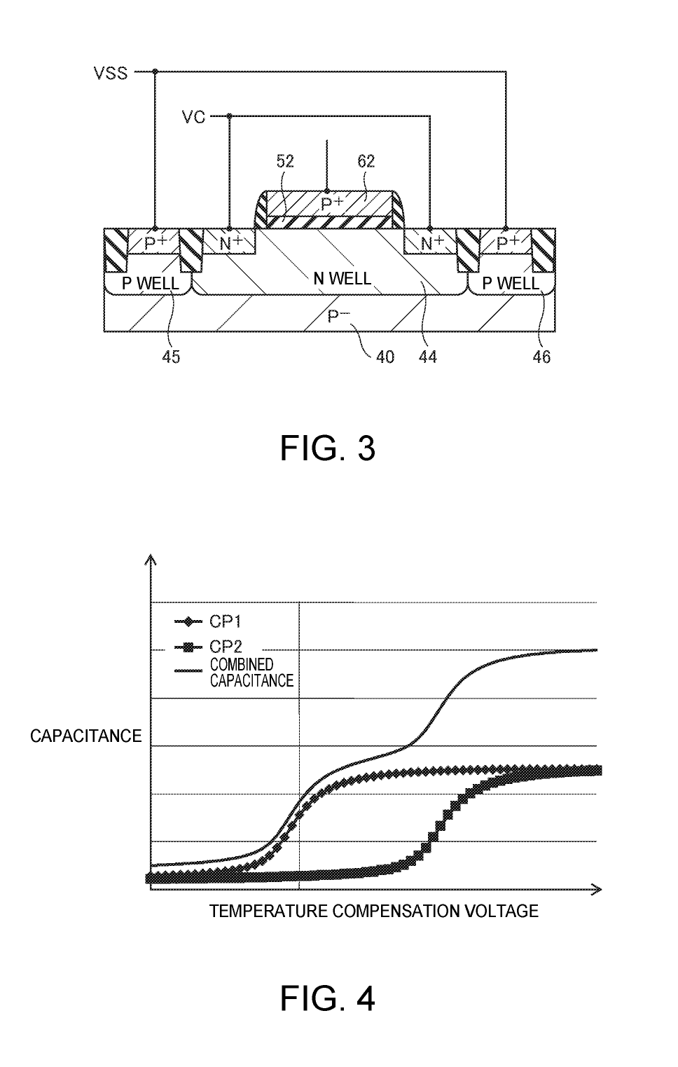

FIG. 3 is a cross-sectional view illustrating an example of the configuration of the second MOS-type variable capacitance element illustrated in FIG. 1. As illustrated in FIG. 3, an N well 44 and P wells 45 and 46 are provided within a P-type semiconductor substrate 40. Furthermore, an N-type contact region (N⁺) for supplying the temperature compensation voltage VC to the N well 44 is provided within the N well 44, and P-type contact regions (P⁺) for supplying the source potential VSS to the semiconductor substrate 40 through the P wells 45 and 46 are provided in the P wells 45 and 46.

The second MOS-type variable capacitance element CV2 includes a second back gate constituted by the N well 44 provided in the semiconductor substrate 40, and a P-type second gate electrode 62 arranged above the second back gate with an insulating film (gate insulator) 52 interposed therebetween. The second gate electrode 62 is formed of polysilicon containing P-type impurities, for example. Here, the effective fixed charge density at the boundary between the insulating film 52 and the second gate electrode 62 is found by multiplying the flat-band voltage shift of the second gate electrode 62 by the capacitance of the insulating film 52.

Referring to FIGS. 1 to 3, the first gate electrode 61 of the first MOS-type variable capacitance element CV1 and the second gate electrode 62 of the second MOS-type variable capacitance element CV2 are electrically connected to the first electrode 11a and the second electrode 11b, respectively, of the crystal resonator 11. Additionally, the temperature compensation circuit 20 supplies the temperature compensation voltage VC to the first back gate of the first MOS-type variable capacitance element CV1 and the second back gate of the second MOS-type variable capacitance element CV2. In this case, the same temperature compensation voltage VC is supplied to the first and second back gates, and thus the first and second back gates can be integrated.

In other words, the N well 41 and N well 44 illustrated in FIGS. 2 and 3 may be integrated. Furthermore, the P well 42 and the P well 45 may be integrated, and the P well 43 and the P well 46 may be integrated. Alternatively, the first and second back gates may be constituted by at least one P well provided in the N-type semiconductor substrate or within the N well. In this case, the polarity of the temperature compensation voltage VC is reversed. In either case, it is necessary for the second back gate of the second MOS-type variable capacitance element CV2 to have the same conductivity type as the first back gate of the first MOS-type variable capacitance element CV1.

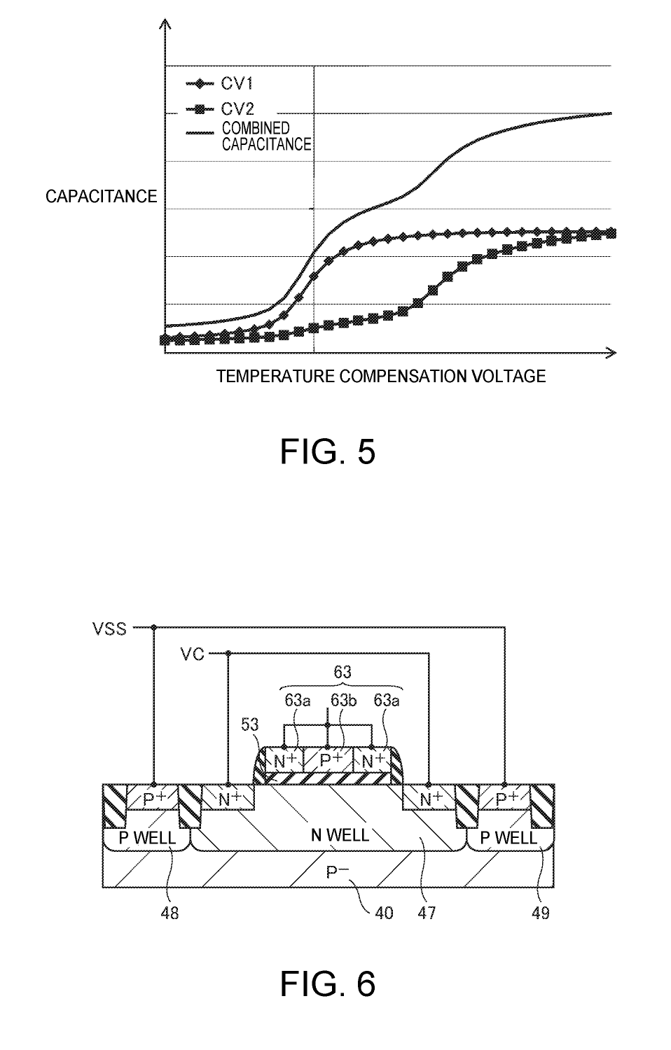

FIG. 4 is a diagram illustrating an example of capacitance changes in a known temperature-compensated crystal oscillator, whereas FIG. 5 is a diagram illustrating an example of capacitance changes in the temperature-compensated crystal oscillator according to the first embodiment of the invention. In FIGS. 4 and 5, the horizontal axis represents a temperature compensation voltage, whereas the vertical axis represents the capacitances of the first and second MOS-type variable capacitance elements, and a combined capacitance thereof, in a normalized state.

As the gate voltages of the MOS-type variable capacitance elements are increased, a barrier layer formed in the well (e.g., the N well 41 or 44 illustrated in FIG. 2 or FIG. 3) gradually expands, and the capacitance values of the MOS-type variable capacitance elements gradually decrease. Once the gate voltages of the MOS-type variable capacitance elements have increased to a given level, the expansion of the barrier layer saturates and the capacitance values of the MOS-type variable capacitance elements approach a set value.

A first MOS-type variable capacitance element CP1 and a second MOS-type variable capacitance element CP2 used in the known temperature-compensated crystal oscillator have the same structure. A first bias voltage is applied to one end of the first MOS-type variable capacitance element CP1, and a second bias voltage is applied to one end of the second MOS-type variable capacitance element CP2. A temperature compensation voltage is applied to the other end of the first MOS-type variable capacitance element CP1 and the other end of the second MOS-type variable capacitance element CP2.

For example, setting the second bias voltage to be 1 V higher than the first bias voltage results in the capacitance change curve of the second MOS-type variable capacitance element CP2 shifting by 1 V to the right in FIG. 4, relative to the capacitance change curve of the first MOS-type variable capacitance element CP1. The combined capacitance illustrated in FIG. 4 is obtained by adding together the capacitance of the first MOS-type variable capacitance element CP1 and the capacitance of the second MOS-type variable capacitance element CP2, which are connected in parallel in terms of AC current.

On the other hand, the first MOS-type variable capacitance element CV1 and the second MOS-type variable capacitance element CV2 used in the temperature-compensated crystal oscillator illustrated in FIG. 1 have mutually-different flat band voltages due to the difference between the conductive types of the gate electrodes. Accordingly, the capacitance change curve of the first MOS-type variable capacitance element CV1 and the capacitance change curve of the second MOS-type variable capacitance element CV2 are shifted in the horizontal axis direction in FIG. 5, even when the same DC voltage is applied to one end of the first MOS-type variable capacitance element CV1 and one end of the second MOS-type variable capacitance element CV2, and the temperature compensation voltage is applied to the other end of the first MOS-type variable capacitance element CV1 and the other end of the second MOS-type variable capacitance element CV2. The combined capacitance illustrated in FIG. 5 is obtained by adding together the capacitance of the first MOS-type variable capacitance element CV1 and the capacitance of the second MOS-type variable capacitance element CV2, which are connected in parallel in terms of AC current.

Thus according to this embodiment, the first MOS-type variable capacitance element CV1, which includes the N-type first gate electrode 61 (FIG. 2), and the second MOS-type variable capacitance element CV2, which includes the P-type second gate electrode 62 (FIG. 3), have mutually-different flat band voltages. Thus connecting the first MOS-type variable capacitance element CV1 and the second MOS-type variable capacitance element CV2 in parallel in terms of AC current makes it possible to broaden the range of variation of the oscillation frequency without increasing the scale of the circuitry for generating the voltage applied to the MOS-type variable capacitance elements.

### Second Embodiment

In a second embodiment of the invention, the configurations of the first MOS-type variable capacitance element CV1 and the second MOS-type variable capacitance element CV2 used in the temperature-compensated crystal oscillator illustrated in FIG. 1 are different from those in the first embodiment. The second embodiment may be the same as the first embodiment in other respects.

FIG. 6 is a cross-sectional view illustrating an example of the configuration of the MOS-type variable capacitance elements according to the second embodiment. As illustrated in FIG. 6, an N well 47 and P wells 48 and 49 are provided within a P-type semiconductor substrate 40. Furthermore, an N-type contact region (N⁺) for supplying the temperature compensation voltage VC to the N well 47 is provided within the N well 47, and P-type contact regions (P⁺) for supplying the source potential VSS to the semiconductor substrate 40 through the P wells 48 and 49 are provided in the P wells 48 and 49.

For example, the first MOS-type variable capacitance element CV1 includes a first back gate constituted by the N well 47 provided in the semiconductor substrate 40, and a first gate electrode 63 arranged above the first back gate with an insulating film (gate insulator) 53 interposed therebetween. The first gate electrode 63 includes an N-type part 63a and a P-type part 63b, and is constituted by polysilicon in which, for example, a predetermined part contains P-type impurities and the remaining parts contain N-type impurities.

Likewise, the second MOS-type variable capacitance element CV2 includes a second back gate constituted by the N well provided in the semiconductor substrate 40, and a second gate electrode arranged above the second back gate with an insulating film interposed therebetween. The second gate electrode includes an N-type part and a P-type part. However, the surface area ratio of the N-type part and the P-type part of the second gate electrode when viewed in plan view may be different from that surface area ratio in the first MOS-type variable capacitance element CV1.

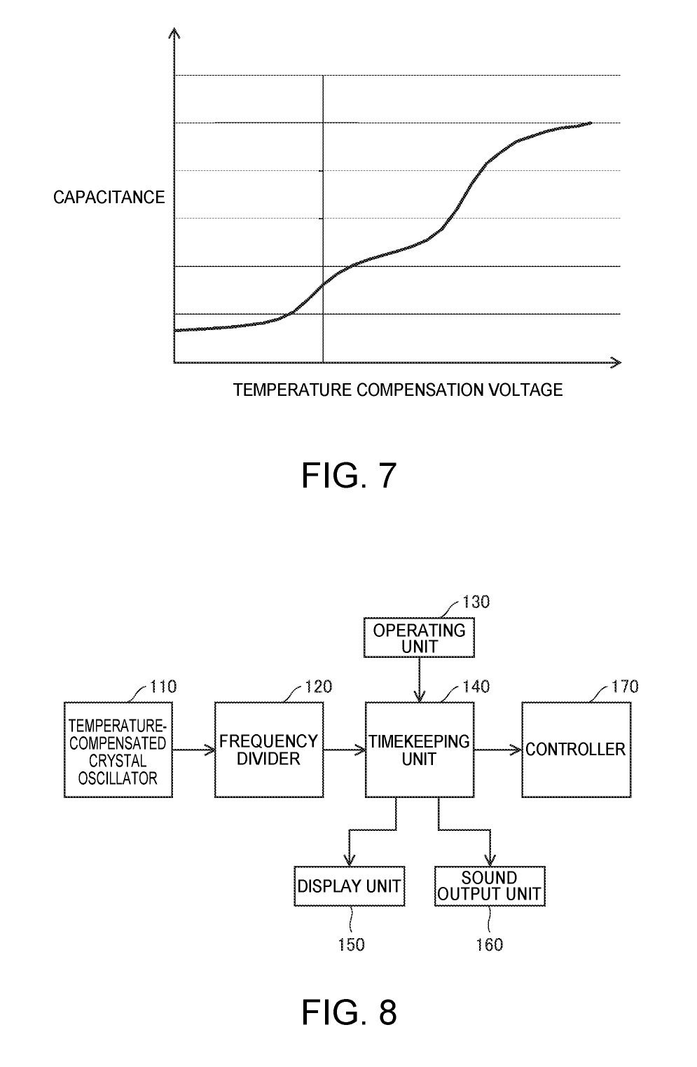

FIG. 7 is a diagram illustrating an example of capacitance changes in the temperature-compensated crystal oscillator according to the second embodiment of the invention. In FIG. 7, the horizontal axis represents a temperature compensation voltage, whereas the vertical axis represents the combined capacitance of the first and second MOS-type variable capacitance elements in a normalized state. In the first and second gate electrodes of the first and second MOS-type variable capacitance elements, the surface area ratios of N-type parts to P-type parts when viewed in plan view are 4:1.

Because the flat band voltage is different between the N-type parts and the P-type parts of the gate electrodes, the capacitance change curve of the MOS-type variable capacitance element illustrated in FIG. 6 is between the capacitance change curve of the MOS-type variable capacitance element having the N-type gate electrode and the capacitance change curve of the MOS-type variable capacitance element having the P-type gate electrode. The combined capacitance illustrated in FIG. 7 is obtained by adding together the capacitance of the first MOS-type variable capacitance element CV1 and the capacitance of the second MOS-type variable capacitance element CV2, which are connected in parallel in terms of AC current.

Thus according to this embodiment, the first MOS-type variable capacitance element CV1 and the second MOS-type variable capacitance element CV2 have mutually-different flat band voltages between the N-type parts and the P-type parts in the first and second gate electrodes. Thus connecting the first MOS-type variable capacitance element CV1 and the second MOS-type variable capacitance element CV2 in parallel in terms of AC current makes it possible to broaden the range of variation of the oscillation frequency without increasing the scale of the circuitry for generating the voltage applied to the MOS-type variable capacitance elements.

Electronic Device

An electronic device employing the temperature-compensated crystal oscillator according to any of the embodiments of the invention will be described next.

FIG. 8 is a block diagram illustrating an example of the configuration of an electronic device according to an embodiment of the invention. A timepiece and a timer will be described as examples of the electronic device hereinafter. The timepiece according to an embodiment of the invention includes a temperature-compensated crystal oscillator 110 according to any of the embodiments of the invention, a frequency divider 120, an operating unit 130, a timekeeping unit 140, a display unit 150, and a sound output unit 160. The timer according to an embodiment of the invention includes a controller 170 instead of the sound output unit 160. Note that some of the constituent elements illustrated in FIG. 8 may be omitted or changed, or constituent elements aside from those illustrated in FIG. 8 may be added.

The frequency divider 120 is constituted by a plurality of flip-flops and the like, for example, and generates a frequency-divided clock signal for timekeeping by frequency-dividing a clock signal supplied from the temperature-compensated crystal oscillator 110. The timekeeping unit 140 is constituted by a counter or the like, for example, and carries out timekeeping operations on the basis of the frequency-divided clock signal supplied from the frequency divider 120, generates a display signal expressing the current time or an alarm time, generates an alarm signal for emitting an alarm sound, and so on.

The operating unit 130 is used to set the current time or the alarm time in the timekeeping unit 140. The display unit 150 displays the current time or the alarm time in accordance with the display signal supplied from the timekeeping unit 140. The sound output unit 160 emits an alarm sound in accordance with the alarm signal supplied from the timekeeping unit 140.

In the timer, the alarm function is replaced with a timer function. In other words, the timekeeping unit 140 generates a timer signal indicating that the current time matches a set time. The controller 170 turns a device connected to the timer on or off in accordance with the timer signal supplied from the timekeeping unit 140.

According to this embodiment, an electronic device capable of operating accurately throughout a broad temperature range can be provided at low cost by using the temperature-compensated crystal oscillator 110, which broadens the range of variation of the oscillation frequency without increasing the scale of the circuitry for generating the voltage applied to the MOS-type variable capacitance elements.

The invention is not limited to the embodiments described thus far. Many modifications can be made, without departing from the technical spirit of the invention, by one of ordinary skill in the technical field. For example, multiple embodiments selected from the embodiments described above can be combined.

This application claims priority from Japanese Patent Application No. 2017-224381 filed in the Japanese Patent Office on Nov. 22, 2017, the entire disclosure of which is hereby incorporated by reference in its entirely.

What is claimed is:

1. A temperature-compensated crystal oscillator comprising:
a crystal resonator including a first electrode and a second electrode;
a first MOS-type variable capacitance element having one end electrically connected to the first electrode or the second electrode of the crystal resonator;
a second MOS-type variable capacitance element having one end electrically connected to the first electrode or the second electrode of the crystal resonator; and
a temperature compensation circuit that applies a temperature compensation voltage, which changes in accordance with a temperature, to another end of the first MOS-type variable capacitance element and another end of the second MOS-type variable capacitance element,
wherein the first MOS-type variable capacitance element includes a first back gate provided within a semiconductor substrate, an N-type first gate electrode and an insulating film interposed between the first back gate and the N-type first gate electrode; and
the second MOS-type variable capacitance element includes a second back gate provided within the semiconductor substrate and having the same conductivity type as the first back gate, a P-type second gate electrode and an insulating film interposed between the second back gate and the P-type second gate electrode.

2. A temperature-compensated crystal oscillator comprising:
a crystal resonator including a first electrode and a second electrode;
a first MOS-type variable capacitance element having one end electrically connected to the first electrode or the second electrode of the crystal resonator;
a second MOS-type variable capacitance element having one end electrically connected to the first electrode or the second electrode of the crystal resonator; and
a temperature compensation circuit that applies a temperature compensation voltage, which changes in accordance with a temperature, to another end of the first MOS-type variable capacitance elements and another end of the second MOS-type variable capacitance elements,
wherein the first MOS-type variable capacitance element includes a first back gate provided within a semiconductor substrate, a first gate electrode and an insulating film interposed between the first back gate and the first gate electrode, the first gate electrode including an N-type part and a P-type part; and
the second MOS-type variable capacitance element includes a second back gate provided within the semiconductor substrate and having the same conductivity type as the first back gate, a second gate electrode and an insulating film interposed between the second back gate and the second gate electrode, the second gate electrode including an N-type part and a P-type part.

3. The temperature-compensated crystal oscillator according to claim 1, further comprising:
an amplifier circuit that is connected between the first electrode and the second electrode of the crystal resonator and that carries out inverse amplifying operations.

4. The temperature-compensated crystal oscillator according to claim 2, further comprising:
an amplifier circuit that is connected between the first electrode and the second electrode of the crystal resonator and that carries out inverse amplifying operations.

5. The temperature-compensated crystal oscillator according to claim 1,
wherein the first gate electrode of the first MOS-type variable capacitance element and the second gate electrode of the second MOS-type variable capacitance element are electrically connected to the first and second electrodes, respectively, of the crystal resonator; and
the temperature compensation circuit supplies the temperature compensation voltage to the first back gate of the first MOS-type variable capacitance element and the second back gate of the second MOS-type variable capacitance element.

6. The temperature-compensated crystal oscillator according to claim 2,
wherein the first gate electrode of the first MOS-type variable capacitance element and the second gate electrode of the second MOS-type variable capacitance element are electrically connected to the first and second electrodes, respectively, of the crystal resonator; and
the temperature compensation circuit supplies the temperature compensation voltage to the first back gate of the first MOS-type variable capacitance element and the second back gate of the second MOS-type variable capacitance element.

7. An electronic device comprising the temperature-compensated crystal oscillator according to claim 1.

8. An electronic device comprising the temperature-compensated crystal oscillator according to claim 2.
